(19) United States
(12) Patent Application Publication
(10) Pub. No.: US 2026/0327795 A1
(43) Pub. Date: Oct. 22, 2026

(54) VAPOR DEPOSITION APPARATUS AND UPPER LINER THEREOF

(71) Applicant: Advanced Micro-Fabrication Equipment Inc. China, Shanghai (CN)

(72) Inventors: Shiping GUO, Shanghai (CN); Zhiyou DU, Shanghai (CN); Ning ZHOU, Shanghai (CN); Jiahao LUO, Shanghai (CN); Yong JIANG, Shanghai (CN); Jiejie HUANG, Shanghai (CN); Wen HUANG, Shanghai (CN)

(21) Appl. No.: 19/702,802

(22) Filed: Jun. 9, 2026

Related U.S. Application Data
(63) Continuation of application No. PCT/CN2024/130131, filed on Nov. 6, 2024.

(30) Foreign Application Priority Data
Dec. 27, 2023 (CN) 202311828579.6

(51) Int. Cl. C23C 16/455; C23C 16/458; C23C 16/46

(52) U.S. Cl. CPC C23C 16/45502; C23C 16/4585; C23C 16/46

(57) ABSTRACT

Disclosed are a vapor deposition apparatus and a top liner thereof. The apparatus includes a top liner and a gas injection apparatus. The top liner is formed by rotating a second busbar around a central shaft of the gas injection apparatus. The second busbar is formed by a first busbar rotating around a start point of the first busbar at a set angle in a vertical direction. The first busbar has the start point close to the central shaft and an end point away from the central shaft. For any two points x, y on the first busbar, their vertical distances to susceptor are h₁, h₂, respectively, their horizontal distances to the central shaft are l₁, l₂, respectively, and the points x, y satisfy h₁×l₁=h₂×l₂. Alternatively, the top liner is formed by a straight third busbar rotating around the central shaft. The third busbar and the first busbar share the start point and the end point.

### CROSS REFERENCE TO RELATED APPLICATION

This application is a continuation application of International Application No. PCT/CN2024/130131, filed on Nov. 6, 2024, which claims priority to Chinese Application No. 202311828579.6, filed on Dec. 27, 2023. All of the above-referenced applications are incorporated herein by reference in their entirety.

### TECHNICAL FIELD

The present disclosure relates to the field of semiconductor devices, in particular to a vapor deposition apparatus and a top liner thereof.

### BACKGROUND

Chemical vapor deposition (CVD) refers to a process in which reaction substances in a gaseous state undergo a chemical reaction on a surface of a wafer to form a thin film of a desired material. A chemical vapor deposition process is capable of depositing diverse materials, encompassing a wide spectrum of insulating materials, most semiconductor materials, and metallic materials.

A CVD apparatus usually includes a reaction chamber, which includes a chamber and a chamber lid. A susceptor is disposed in the reaction chamber, and one or more wafers are placed on the susceptor. A heater is also disposed below the susceptor, and the susceptor uniformly transfers heat radiated by the heater to the wafers. A corrosion-resistant top liner is further disposed below the chamber lid, and a reaction area is formed between a lower surface of the top liner and an upper surface of the susceptor.

A gas injection apparatus (opposite to a central zone of the susceptor) passes through the top liner and is fixedly mounted on the chamber lid, and a process gas is introduced into the reaction area from the gas injection apparatus to process the wafers placed on the susceptor. In the process flow, the susceptor drives the wafers to rotate at a high speed, such that different types of process gases on the upper surface of the susceptor are fully mixed driven by the susceptor rotating at the high speed. The process gases react at a specific temperature and deposit on the surface of the wafer W to form a thin film of the desired material. The wafer temperature is one of the important factors affecting the deposition rate of the material on the wafer W.

In order to allow the process gas to flow out of the gas injection apparatus to uniformly pass over the upper surface of the wafer in a laminar flow manner, the top liner is generally parallel to the susceptor. However, as the process gas flows outward in the radial direction of the susceptor, the density of the process gas gradually decreases, which affects the growth rate of the thin film. To ensure the growth rate of the thin film, a large amount of process gas needs to be supplied into the reaction chamber, resulting in low utilization efficiency of the process gas. Especially when wafers with larger diameters are produced, the waste of process gas becomes particularly significant.

How to improve the utilization rate of the process gas and the growth rate of the thin film while ensuring the uniformity of the thin film on the wafer surface is a difficult problem to be solved at present.

### SUMMARY

An objective of the present disclosure is to provide a vapor deposition apparatus and a top liner thereof. The top liner of the vapor deposition apparatus is formed by rotating a second busbar or a third busbar around a central shaft of a gas injection apparatus. For points on the second busbar and the third busbar, vertical distances between these points and a wafer supporting surface and horizontal distances between these points and the central shaft of the gas injection apparatus satisfy a set condition. By changing the shape of the top liner, the utilization efficiency of the process gas (i.e., the source efficiency) in the reaction chamber and the deposition rate of the thin film on the surface of the wafer are greatly improved, and the uniformity of the thickness of the thin film on the surface of the wafer is further considered. Through the vapor deposition apparatus provided by the present disclosure, a high-quality thin film can be rapidly grown on the wafer surface while consuming less process gas.

To achieve the above objective, the present disclosure provides a vapor deposition apparatus, including a reaction chamber, a susceptor being disposed at a lower part of the reaction chamber and an upper surface of the susceptor being a wafer supporting surface, where the vapor deposition apparatus includes:
a top liner, disposed in the reaction chamber and opposite to the wafer supporting surface, and a reaction area being formed between the top liner and the wafer supporting surface; and
a gas injection apparatus, the gas injection apparatus being configured to transversely inject a process gas into the reaction area, where
the top liner is formed by a second busbar rotating around a central shaft of the gas injection apparatus, the second busbar is formed by a first busbar rotating around a start point of the first busbar at a set angle in a vertical direction, and the first busbar has the start point close to the central shaft and an end point away from the central shaft; points x, y are any two points on the first busbar, vertical distances between the points x, y and the wafer supporting surface are denoted as h₁,h₂, respectively, horizontal distances between the points x, y and the central shaft are denoted as l₁,l₂, respectively, and the points x, y satisfy h₁×l₁=h₂×l₂; and alternatively, the top liner is formed by a third busbar rotating around the central shaft of the gas injection apparatus, the third busbar is a straight line, and the third busbar and the first busbar share the start point and the end point.

Optionally, the angle is [−2°, 5°]; when the first busbar rotates around the start point in a direction close to the wafer supporting surface, the angle is defined as a negative value, and when the first busbar rotates around the start point in a direction away from the wafer supporting surface, the angle is defined as a positive value.

Optionally, the reaction chamber includes a chamber lid, located above the top liner; and a coolant passage is disposed in the chamber lid.

Optionally, a heating apparatus is disposed below the susceptor; the susceptor is virtually divided into a plurality of annular temperature zones in a radial direction of the susceptor, and a temperature difference between adjacent annular temperature zones exceeds a set temperature difference threshold; the chamber lid is virtually divided into a plurality of annular temperature regulation zones corresponding to the plurality of annular temperature zones respectively in a radial direction of the chamber lid; and a distance between the coolant passage in the annular temperature regulation zone and a lower surface of the chamber lid depends on a temperature of the corresponding annular temperature zone.

Optionally, a temperature regulating mechanism is disposed between the chamber lid and the top liner.

Optionally, the temperature regulating mechanism includes a thermal conductive plate, and an upper surface of the thermal conductive plate is attached to the lower surface of the chamber lid.

Optionally, the temperature regulating mechanism further includes a gap formed between the thermal conductive plate and the top liner.

Optionally, the gap first decreases and then increases in a direction away from the gas injection apparatus.

Optionally, a thickness of the thermal conductive plate first increases and then decreases along the direction away from the gas injection apparatus.

Optionally, surface emissivity of the thermal conductive plate first increases and then decreases in the direction away from the gas injection apparatus.

Optionally, the vapor deposition apparatus further includes a heat transfer gas input end and a heat transfer gas output end, configured to provide a flowing heat transfer gas to the gap.

Optionally, components of the heat transfer gas are adjustable.

Optionally, the vapor deposition apparatus further includes a pumping ring, and the pumping ring is disposed around a lower lateral side of the susceptor.

Optionally, the pumping ring includes an inner ring, an outer ring, and a ring top surface that connects the inner ring and the outer ring; and a plurality of pumping holes are formed in the ring top surface in a circumferential direction of the pumping ring.

Optionally, the vapor deposition apparatus further includes a side liner, which is disposed around a periphery of the susceptor and located between the top liner and the pumping ring.

Optionally, an upper end of the side liner is provided with a gas flow guide portion that extends in a direction toward the gas injection apparatus.

Optionally, the top liner further includes a top liner supporting portion that extends from the end point in a direction away from the central shaft, and a bottom surface of the top liner supporting portion is attached to a top surface of the gas flow guide portion.

Optionally, the gas injection apparatus includes gas outlet ends located at different heights, and the gas outlet end closest to the top liner is configured to supply an inert gas.

The present disclosure further provides a top liner, used in a vapor deposition apparatus, where the vapor deposition apparatus includes a reaction chamber, a susceptor being disposed at a lower part of the reaction chamber and an upper surface of the susceptor being a wafer supporting surface;
the top liner is disposed in the reaction chamber and opposite to the wafer supporting surface, and a reaction area is formed between the top liner and the wafer supporting surface; and
the vapor deposition apparatus further includes a gas injection apparatus, the gas injection apparatus being configured to transversely inject a process gas into the reaction area;
the top liner is formed by a second busbar rotating around a central shaft of the gas injection apparatus, the second busbar is formed by a first busbar rotating around a start point of the first busbar at a set angle in a vertical direction, and the first busbar has the start point close to the central shaft and an end point away from the central shaft; points x, y are any two points on the first busbar, vertical distances between the points x, y and the wafer supporting surface are denoted as h₁,h₂, respectively, horizontal distances between the points x, y and the central shaft are denoted as l₁,l₂, respectively, and the points x, y satisfy h₁×l₁=h₂×l₂; and alternatively, the top liner is formed by a third busbar rotating around the central shaft of the gas injection apparatus, the third busbar is a straight line, and the third busbar and the first busbar share the start point and the end point.

Optionally, the angle is [−2°, 5°]; when the first busbar rotates around the start point in a direction close to the wafer supporting surface, the angle is defined as a negative value, and when the first busbar rotates around the start point in a direction away from the wafer supporting surface, the angle is defined as a positive value.

Compared with the prior art, the present disclosure has the following beneficial effects:
1) The top liner on the vapor deposition apparatus provided by the present disclosure is formed by rotating the second busbar or the third busbar around the central shaft of the gas injection apparatus. For points on the second busbar and the third busbar, vertical distances between these points and a wafer supporting surface and horizontal distances between these points and the central shaft of the gas injection apparatus satisfy a set condition. By changing the shape of the top liner, the utilization efficiency of the process gas in the reaction chamber and the deposition rate of the thin film on the surface of the wafer are greatly improved, and the uniformity of the thickness of the thin film on the surface of the wafer is further considered. Through the vapor deposition apparatus provided by the present disclosure, a high-quality thin film can be rapidly grown on the wafer surface while consuming less process gas.
2) The coolant passage is disposed in the chamber lid of the present disclosure, which can effectively take away heat radiated from the susceptor and the wafer to the top liner and reduce deposition of the reactant gas on the surface of the top liner, thereby effectively reducing particulate pollutants in the reaction chamber and significantly improving the yield of the wafer. Meanwhile, the cleaning frequency of the reaction chamber can also be reduced, such that the wafer processing efficiency is greatly improved and the wafer processing cost is obviously reduced.
3) In the present disclosure, according to the temperature difference on the surface of the susceptor, the susceptor is virtually divided into the plurality of annular temperature zones, and the chamber lid is virtually divided into annular temperature regulation zones corresponding to the annular temperature zones. If the temperature of the annular temperature zones is relatively high, the distance between the coolant passage in the corresponding annular temperature regulating zone and the lower surface of the chamber lid is less, and if the temperature of the annular temperature zones is relatively low, the distance between the coolant passage in the corresponding annular temperature regulating zone and the lower surface of the chamber lid is greater. This enables zone-based adjustment of the temperature of the top liner, which helps reduce the temperature gradient across the top liner and prevents deformation thereof. Improving the temperature uniformity of the top liner also enhances the temperature uniformity of the process gas within the reaction chamber (with heat transfer occurring between the top liner and the process gas in the reaction chamber), which is beneficial for growing a thin film of uniform thickness on the wafer surface.
4) The temperature regulating mechanism is disposed between the chamber lid and the top liner and includes the thermal conductive plate disposed between the chamber lid and the top liner and a gap formed between the thermal conductive plate and the top liner. The heat transfer gas in the thermal conductive plate and the gap enhances the heat transfer between the top liner and the chamber lid, which is beneficial to taking away heat of the top liner and preventing the thin film from depositing on the surface of the top liner.
5) In the present disclosure, the thickness, surface emissivity, and gap of the thermal conductive plate vary along the direction away from the gas injection apparatus in accordance with the temperature of the susceptor, thereby achieving zone-wise regulation of the temperature of the top liner and ensuring temperature uniformity thereof.
6) In the present disclosure, the components of the heat transfer gas can be adjusted in real time according to the process of the reaction chamber and the temperature in the reaction chamber, so as to adjust the temperature of the top liner. Deposits on the top liner can be reduced in deposition processes for various materials.

### BRIEF DESCRIPTION OF THE DRAWINGS

To describe the technical solutions in the present disclosure more clearly, the accompanying drawings used in the description are briefly introduced below. Apparently, the accompanying drawings in the following description show one embodiment of the present disclosure. For those of ordinary skill in the art, other drawings may be derived from these drawings without creative effort.

FIG. 1 is a schematic diagram of a vapor deposition apparatus;

FIG. 2 is an A-A view of FIG. 1;

FIG. 3 is a schematic diagram of a vapor deposition apparatus in Embodiment I of the present disclosure;

FIG. 4 is a schematic diagram of a gas injection apparatus in Embodiment I of the present disclosure;

FIG. 5 is a top view of a susceptor, a side liner, and a pumping ring in Embodiment I of the present disclosure;

FIG. 6 is a schematic diagram of a first busbar, a second busbar, and a third busbar in Embodiment I and Embodiment II of the present disclosure;

FIG. 7 is a schematic diagram where a horizontal straight line of the top liner of the vapor deposition apparatus is generated in FIG. 1;

FIG. 8 is a comparison diagram of an average growth rate and a uniformity difference of thin films on a surface of a wafer in a plurality of embodiments;

FIG. 9 is a schematic diagram of a deposition speed of a thin film on a surface of a wafer along a radial direction of the wafer in a plurality of embodiments;

FIG. 10 is a schematic diagram where a susceptor is divided into a plurality of annular temperature zones and a chamber lid is divided into a plurality of annular temperature regulation zones in Embodiment III; and

FIG. 11 is a schematic diagram of a thermal conductive plate having a gradually varied thickness in Embodiment IV.

### DETAILED DESCRIPTION

The following clearly and completely describes the technical solutions in embodiments of the present application with reference to the accompanying drawings in embodiments of the present application. Obviously, the described embodiments are merely some rather than all of embodiments of the present application. Based on embodiments of the present application, all other embodiments obtained by those of ordinary skill in the art without creative efforts fall within the protection scope of the present application.

It should be understood that, when used in this specification and the appended claims of the present application, the term “include” indicates presence of the described feature, entirety, step, operation, element, and/or component, but does not exclude presence or addition of one or more other features, entireties, steps, operations, elements, components, and/or sets thereof.

It should also be understood that the terminology used in the present specification is for the purpose of describing particular embodiments only and is not intended to limit the present application. As used in the present specification and the appended claims, the singular forms “a”, “an”, and “the” are intended to include the plural forms unless the context clearly dictates otherwise.

It should be further understood that, as used in the present specification and the appended claims, the term “and/or” refers to any and all possible combinations of one or more of the associated listed items, and includes such combinations.

As used in this specification and the appended claims, the term “if” may be construed, depending on the context, as “when”, “once”, “in response to determining” or “in response to detecting”. Similarly, the phrases “if determined” or “if [the described condition or event] is detected” may, depending on the context, be interpreted to mean “once determined”, “in response to a determination”, “once [the described condition or event] is detected”, or “in response to detection of [the described condition or event]”.

In addition, in the description of the present application, the terms such as “first”, “second”, “third”, and “fourth” are used only for distinguishing between descriptions, but cannot be understood as indication or implication of relative importance.

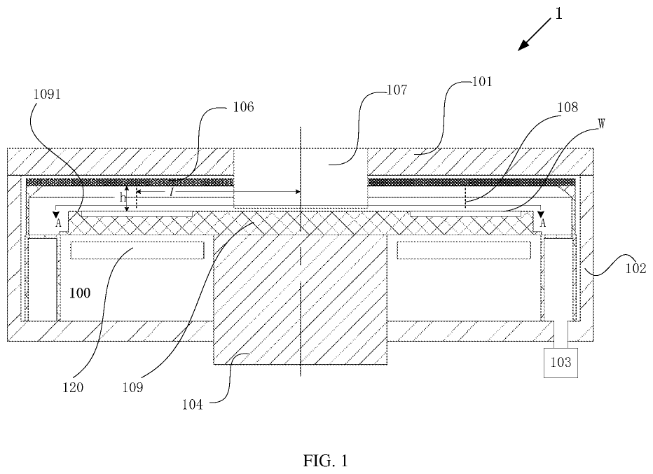

FIG. 1 shows a vapor deposition apparatus 1, which has a reaction chamber 100, where a wafer W can be processed. The reaction chamber 100 includes a chamber lid 101 and a chamber body 102. The chamber lid 101 covers the chamber body 102, and the chamber lid 101 and the chamber body 102 jointly define a sealed processing space. The chamber lid 101 is usually made of a metal material (e.g., stainless steel). Although the chamber body 102 shown in FIG. 1 is cylindrical, the chamber body may also be in other shapes, such as square, hexagonal, octagonal, or any other suitable shape.

As shown in FIG. 1, a top of a gas injection apparatus 107 (usually made of a corrosion-resistant stainless steel material with good thermal conductivity) passes through the chamber lid and is located in the reaction chamber 100. The susceptor 109 is disposed below the gas injection apparatus 107 and is opposite to the gas injection apparatus 107. The upper surface of the susceptor 109 is a wafer supporting surface 1091. A reaction area is formed between the wafer supporting surface 1091 and the chamber lid 101. A gas circuit of the gas injection apparatus 107 communicates with an external process gas supply device (not shown in the figure) to deliver a process gas to the reaction area. The process gas may include carrier gas and reactant gas. The reactant gas may include a Group III gas and a Group V gas. In a typical metal-organic chemical vapor deposition process, the carrier gas may be nitrogen, hydrogen, argon, or other such gases.

The susceptor 109 is usually made of graphite and has good thermal conductivity. A heating element 120 is disposed below the susceptor, the heating element 120 heats the susceptor 109, the susceptor 109 then transfers the heat provided by the heating element 120 to the wafer W, and the process gas reacts at a specific temperature and is deposited on the wafer W to form a thin film of a desired material.

A bottom of the susceptor 109 is fixedly connected to a drive shaft 104 (the drive shaft may be driven by an external motor or cylinder). A bottom of the drive shaft 104 vertically passes through a bottom wall of the chamber body 102 and is located outside the reaction chamber 100. The drive shaft 104 drives the susceptor 109 to rotate at a high speed, such that different types of process gases on the upper surface of the susceptor 109 are fully mixed driven by the high-speed rotation of the susceptor 109.

An exhaust device 103 is configured to discharge gas in the reaction chamber 100, including waste gas generated by reactions and part of the process gas that has not reacted.

The top liner 106 is disposed below the chamber lid 101 to shield heat radiated from the interior of the reaction chamber 100 onto the chamber lid 101 and prevent deposits from being formed on the chamber lid 101. The top liner 106 may be made of graphite. The chamber lid 101 and the top liner 106 in FIG. 1 both have a plate structure, which can avoid a large-scale diffused gas flow in a vertical direction in the reaction chamber 100 to ensure that the gas flow in the reaction chamber 100 is in a laminar flow state, thereby improving the uniformity of gas flow distribution in the reaction chamber 100.

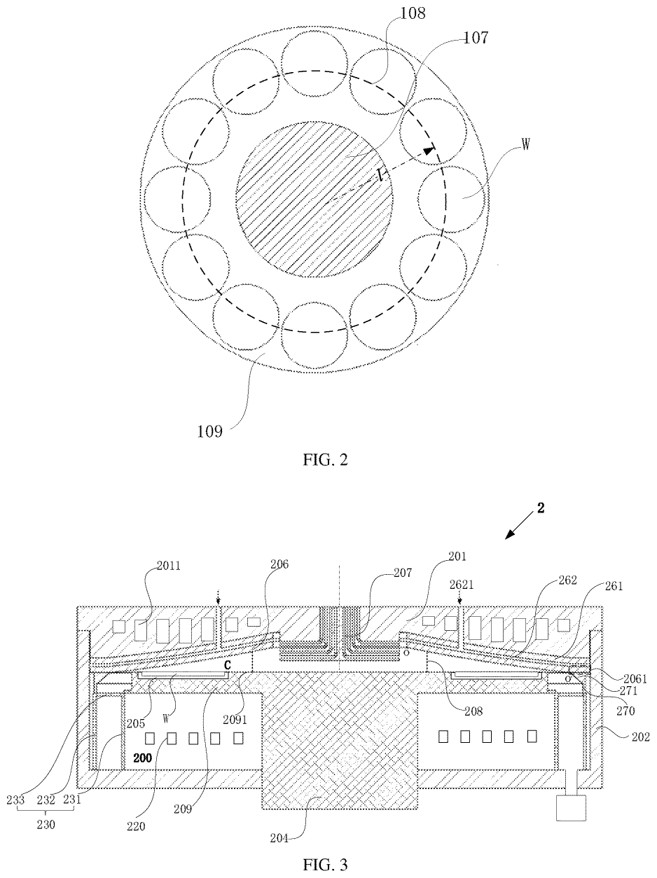

From inside to outside, along the radial direction of the susceptor 109, the area of the flow cross-section 108 of the process gas gradually increases. The flow cross-section 108 is a cylindrical section sharing the same central shaft with the gas injection apparatus 107 in the reaction chamber 100. The top and bottom of the cylindrical section are respectively the top liner 106 and the wafer supporting surface 1091. As shown in FIG. 1 and FIG. 2, when a horizontal distance between the flow cross-section 108 and the central shaft of the gas injection apparatus is l, the area of the flow cross-section 108 is s=2π×l×h, and h represents a height of the flow cross-section 108. When the top liner 106 is of a plate structure, h is a vertical distance between the top liner 106 and the wafer supporting surface 1091.

While the process gas flowing from the gas injection apparatus 107 moves in a direction away from the gas injection apparatus 107, the area of the flow cross-section 108 gradually increases, such that the density of the process gas gradually decreases and the thin film deposition rate also becomes slower. To prevent the process gas inside the reaction chamber 100 from becoming gradually diluted along the flow direction thereof, it is necessary to increase the supply of process gas, which results in the supply amount being far greater than the amount required for the actual reaction, thereby causing waste.

On the other hand, the top liner 106 is subjected to relatively large thermal radiation, and process gas tends to deposit on the surface of the top liner 106. After the deposits on the surface of the top liner 106 peel off, they tend to form particulate contaminants inside the reaction chamber 100, significantly reducing the yield of the wafer W.

The present disclosure provides a vapor deposition apparatus. A top liner of the vapor deposition apparatus is formed by rotating a second busbar or a third busbar around a central shaft of the gas injection apparatus 107. For points on the second busbar and the third busbar, vertical distances between these points and a wafer supporting surface 1091 and horizontal distances between these points and the central shaft of the gas injection apparatus satisfy a set condition. By changing the shape of the top liner 106, the utilization efficiency of the process gas in the reaction chamber 100 and the deposition rate of the thin film on the surface of the wafer are greatly improved, and the uniformity of the thickness of the thin film on the surface of the wafer is further considered. Through the vapor deposition apparatus provided by the present disclosure, a high-quality thin film can be rapidly grown on the wafer surface. Meanwhile, the present disclosure can also adjust the temperature of the top liner 106 in a regional manner, rapidly conducting heat away from the top liner 106 while improving temperature uniformity of the top liner 106. This not only greatly reduces deposits on the surface of the top liner 106, but also prevents the top liner 106 from deformation and damage due to thermal stress.

### Embodiment I

The present disclosure provides a vapor deposition apparatus 2, as shown in FIG. 3, including a reaction chamber 200. The reaction chamber 200 includes a chamber lid 201 and a chamber body 202. A susceptor 209, a gas injection apparatus 207, a top liner 206, a pumping ring 230, and a side liner 270 are disposed in the reaction chamber 200, and the chamber lid 201 is located above the top liner 206.

The susceptor 209 is disposed in a lower portion of the reaction chamber 200 and an upper surface of the susceptor 209 is a wafer supporting surface 2091. The top liner 206 is opposite to the wafer supporting surface 2091, and a reaction area C is formed between a lower surface of the top liner 206 and an upper surface of the susceptor 209. A heating apparatus 220 is disposed below the susceptor 209, and the susceptor 209 transfers the heat provided by the heating apparatus 220 to the wafer W, and the process gas reacts at a specific temperature and is deposited on the wafer W to form a thin film of a desired material.

In this embodiment, as shown in FIG. 3, along a circumferential direction of the susceptor 209, a plurality of recesses are disposed on an upper surface of the susceptor 209, and a plurality of wafer carriers 205 for placing wafers W are respectively disposed in the plurality of recesses. A special gas passage (not shown in the figure) is disposed in each recess and is configured to introduce a gas with a certain pressure between the wafer carrier 205 and the susceptor 209, such that the wafer carrier 205 can be lifted by the gas to leave the surface of the susceptor, levitated at a predetermined height and rotated about the central axis thereof. A drive shaft 204 is fixedly connected to a bottom of the susceptor 209 to drive the susceptor 209, which in turn drives the wafer carrier 205 to rotate around the center of the susceptor at a high speed. When the wafer carrier 205 is driven to rotate and revolve, the different types of process gases reaching the upper surface of the wafer are uniformly distributed and deposited on the wafer W.

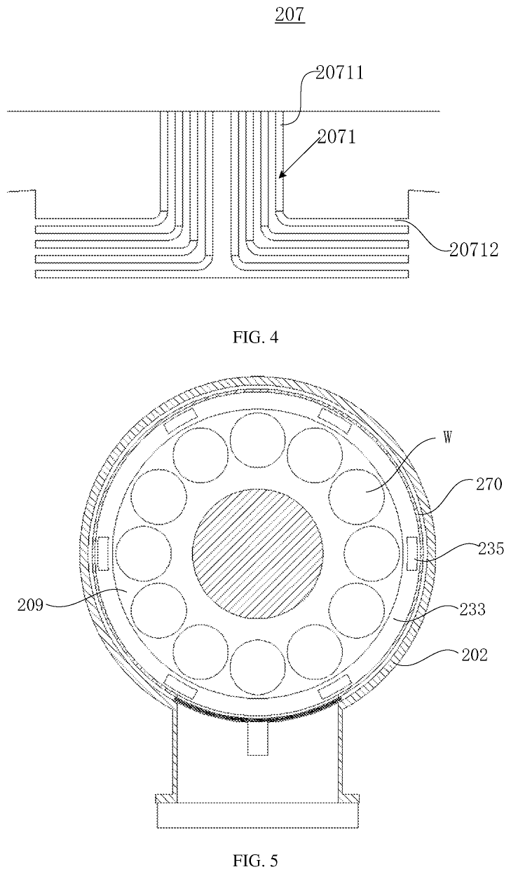

As shown in FIG. 4, the gas injection apparatus 207 is internally provided with a plurality of gas injection pipelines 2071. A gas injection end 20711 of each of the gas injection pipelines 2071 is in gas communication with an external process gas supply device. The gas outlet end 20712 of each gas injection pipeline 2071 has a horizontal in-line structure (the length direction thereof is parallel to the radial direction of the susceptor 209) for transversely injecting the process gas into the reaction area C, such that the process gas passes over the surface of the wafer horizontally as much as possible and is uniformly distributed on the surface of the wafer, thereby improving the uniformity of the thin film deposited on the surface of the wafer. The gas outlet ends 20712 of different types of process gases have different heights. Therefore, various process gases can be injected into the reaction chamber 200 layer by layer in the vertical direction, such that the various process gases are prevented from reacting in advance before they arrive at the surface of the wafer W.

As shown in FIG. 3 and FIG. 5, the pumping ring 230 is disposed around the lower lateral side of the susceptor 209. The pumping ring 230 includes an inner ring 231, an outer ring 232, and a ring top surface 233 that connects the inner ring and the outer ring. As shown in FIG. 5, a plurality of pumping holes 235 are formed in the ring top surface 233 in a circumferential direction of the pumping ring 230. The gas in the reaction chamber 200 is sequentially discharged out of the reaction chamber 200 through the pumping ring 230 and the exhaust device.

As shown in FIG. 3 and FIG. 5, the side liner 270 is disposed around a periphery of the susceptor 209 and is located between the top liner 206 and the pumping ring 230. The side liner 270 prevents the process gas from depositing on the inner side wall of the reaction chamber 200. In this embodiment, as shown in FIG. 3, the side liner 270 is provided with a gas flow guide portion 271 that extends in a direction toward the gas injection apparatus 207. The gas flow guide portion 271 has an annular structure, and the inner diameter thereof increases gradually from top to bottom. Through the gas flow guide portion 271, the process gas is guided to the pumping ring 230.

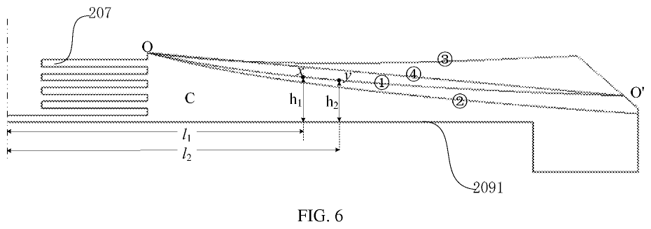

In this embodiment, the top liner 206 is formed by rotating the first busbar \textcircled{1} around the central shaft of the gas injection apparatus 207. As shown in FIG. 6, the first busbar \textcircled{1} has a start point close to the central shaft and an end point O′ away from the central shaft. The start point is an end point of the top liner 206 closest to the gas injection apparatus 207. The points x, y are any two points on the first busbar \textcircled{1}. The vertical distances between the points x, y and the wafer supporting surface 2091 are respectively denoted as h₁,h₂, and the horizontal distances between the points x, y and the central shaft of the gas injection apparatus are respectively denoted as l₁,l₂. The points x, y satisfy h₁×l₁=h₂×l₂.

In this embodiment, as shown in FIG. 3, the end point O′ is located on the top surface of the gas flow guide portion 271. Along a direction parallel to the radial direction of the susceptor, a horizontal section is formed by extending horizontally outward from the end point O′. The horizontal section rotates around the central shaft of the gas injection apparatus 207 to form an annular top liner supporting portion 2061. The bottom surface of the top liner supporting portion 2061 is attached to the top surface of the gas flow guide portion 271. The gas flow guide portion 271 supports the top liner supporting portion 2061. It is worth noting that the bottom surface of the top liner supporting portion 2061 and the top surface of the side liner 270 may not be horizontal surfaces, as long as they fit together properly.

As shown in FIG. 3, the flow cross-section 208 of the process gas is a cylindrical section in the reaction chamber 200 sharing the same central shaft with the gas injection apparatus 207. The top and bottom of the flow cross-section 208 are respectively the top liner 206 and the wafer supporting surface 2091. It is easily understood that the flow cross-section 208 corresponding to the point x and the flow cross-section 208 corresponding to the point y have the same area S, S=2π×h₁×l₁. That is, in the present disclosure, through the top liner 206 generated by the first busbar \textcircled{1}, in the radial direction of the susceptor 209, the areas of the flow cross-sections of the process gas are equal everywhere. Therefore, in this embodiment, in a direction away from the gas injection apparatus 207, the concentration gradient of the process gas is relatively smaller (the decrease in process gas concentration is mainly attributed to the continuous reaction and deposition of the process gas during flow). Through the present disclosure, the utilization efficiency of the process gas is greatly increased, the amount of the process gas used is reduced, and the processing cost of the wafer W is significantly reduced.

In another embodiment, an inert gas may be further introduced into the reaction area C from the gas outlet end 20712 closest to the top liner 206, such that a separating layer is formed between the process gas participating in the reaction and the top liner 206. This is not only beneficial for reducing the deposits on the surface of the top liner 206, but also forces the process gas participating in the reaction to be closer to the surface of the wafer, thereby increasing the utilization efficiency of the process gas.

The rate of chemical reactions on the wafer surface is affected by the concentration of process gas on the wafer surface. In this embodiment, along the direction away from the gas injection apparatus 207, the distance between the top liner 206 and the wafer supporting surface 2091 decreases gradually. The process gas flowing out from the gas injection apparatus 207 is forced by the top liner 206 to flow to the wafer supporting surface 2091. The process gas originally delivered along the horizontal direction acquires a speed component in a vertical direction, such that more process gas is delivered toward the surface of the wafer to participate in the chemical reactions on the surface of the wafer. Therefore, through the present disclosure, the deposition rate of the thin film on the surface of the wafer is increased.

In an experiment, a thin film made of the same material is deposited on the wafer W with the same size (the wafer W revolves with the susceptor 209 while rotating) using the vapor deposition apparatus 1 with the plate top liner 106 and the vapor deposition apparatus 2 (in which the top liner 206 is generated by the first busbar \textcircled{1}) in this embodiment. In this experiment, the reaction chambers 200 of the vapor deposition apparatus 1 and the vapor deposition apparatus 2 have the same diameter, and are equipped with susceptors of the same size. In this experiment, the diameter of the wafer is about 150 mm. In the vapor deposition apparatus 1, the vertical distance between the top liner 106 and the wafer supporting surface 2091 is the same as the vertical distance between the start point of the top liner 206 in the vapor deposition apparatus 2 and the wafer supporting surface 2091. It should be emphasized that the above data is merely an example, rather than limiting the present disclosure.

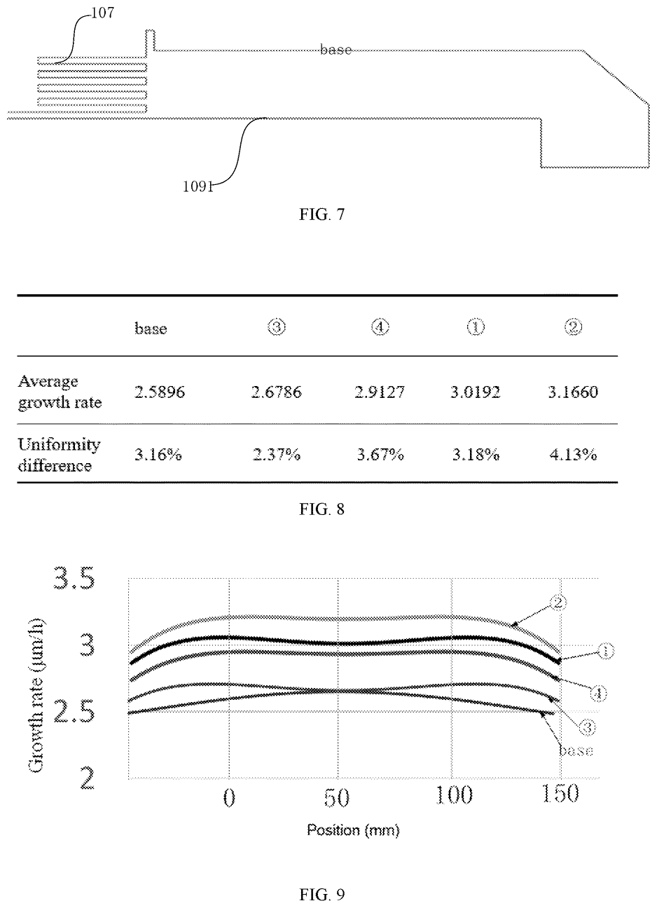

As shown in FIG. 7, the plate top liner 106 of the vapor deposition apparatus 1 may be regarded as being formed by rotating a horizontal straight line (base) around the central shaft of the gas injection apparatus 107. When the top liner 106 is obtained by rotating the horizontal straight line, as shown in FIG. 8, the average growth speed of the thin film on the surface of the wafer is 2.5896 μm/h, and the variation in film thickness uniformity is 3.16%. A calculation formula of the variation in film thickness uniformity is (GRₘₐₓ−GRₘᵢₙ)/GRₐᵥₑ/2, where GRₘₐₓ and GRₘᵢₙ are respectively maximum and minimum growth rates of the thin film on the surface of the wafer, and GRₐᵥₑ is the average growth rate of the thin film on the surface of the wafer. Under ideal conditions, it is desirable that the average growth rate of the thin film be as high as possible and that the variation in film thickness uniformity be as small as possible.

In the above experiment, when the top liner 206 obtained by employing the first busbar \textcircled{1} is used for a CVD process, as shown in FIG. 8, the average growth rate of the thin film on the surface of the wafer is 3.0192 μm/h, and the variation in film thickness uniformity is 3.18%. As shown in FIG. 9, at every position in the radial direction of the wafer, the growth rate of the wafer corresponding to the first busbar \textcircled{1} is always higher than that corresponding to the horizontal straight line base. The above data indicate that the vapor deposition apparatus 2 in this embodiment also takes into account the uniformity of the thickness of the thin film on the surface of the wafer while significantly increasing the growth rate of the thin film. The vapor deposition apparatus 2 can be used to grow a high-quality thin film rapidly on the surface of the wafer.

In the present disclosure, the top liner 206 may also be formed by rotating the second busbar around the central shaft of the gas injection apparatus 207. The second busbar is formed by rotating the first busbar \textcircled{1} by a predetermined angle in the vertical direction about its starting point O. Definition: when the first busbar \textcircled{1} rotates toward a direction close to the wafer supporting surface 2091 around its start point O, the angle is a negative value; and when the first busbar \textcircled{1} rotates toward a direction away from the wafer supporting surface 2091 around its start point O, the angle is a positive value. In the present disclosure, the angle is [−2°, 5°], including −2°, (−2°, 0°), 0°, (0°, 5°), 5°, (−2°, 5°), and the like.

In another embodiment, as shown in FIG. 6, the second busbar \textcircled{2} is obtained by rotating the first busbar \textcircled{1} by −2°. In this embodiment, along the direction away from the gas injection apparatus 207, the area of the flow cross-section 208 gradually decreases (less than S), compared with the top liner 206 generated by the first busbar \textcircled{1}, the top liner 206 in this embodiment may deliver more process gas to the surface of the wafer, which can not only further reduce the input amount of the process gas, but also further improve the average growth rate of the thin film on the surface of the wafer.

As shown in FIG. 9, at every position in the radial direction of the wafer, the growth rate of the wafer corresponding to the second busbar \textcircled{2} is always higher than that corresponding to the first busbar \textcircled{1}. As shown in FIG. 8, the average growth rate of the thin film on the surface of the wafer corresponding to the second busbar \textcircled{2}0 is 3.1660 μm/h, and the variation in film thickness uniformity is 4.13%. It may be seen that compared with the variation (3.18%) in film thickness uniformity corresponding to the busbar \textcircled{1}, the variation in film thickness uniformity corresponding to the second busbar \textcircled{2} increases slightly within an acceptable range.

In another embodiment, as shown in FIG. 6, the second busbar \textcircled{3} is obtained by rotating the first busbar \textcircled{1} by 5°. As shown in FIG. 9, at every position in the radial direction of the wafer, the growth rate of the wafer corresponding to the second busbar \textcircled{3} is always higher than that corresponding to the first busbar \textcircled{1}. In this embodiment, although along the direction away from the gas injection apparatus 207, the area of the flow cross-section 208 still gradually increases, compared with the top liner 106 employing the plate, the input amount of the process gas may still be reduced and the source efficiency of the process gas is improved. In this embodiment, as shown in FIG. 8, the average growth rate of the thin film on the surface of the wafer is 2.6786 μm/h, and the variation in film thickness uniformity is 2.37%. Compared with the top liner employing the plate, this embodiment not only increases the average growth rate of the thin film on the surface of the wafer, but also decreases the variation in film thickness uniformity, which is a preferred embodiment.

### Embodiment II

The top liner 206 in this embodiment is formed by rotating the third busbar \textcircled{4} around the central shaft of the gas injection apparatus 207. As shown in FIG. 6, the third busbar \textcircled{4} is a straight line, the third busbar \textcircled{4} and the first busbar \textcircled{1} share the start point O and the end point O′, and the third busbar \textcircled{4} is located between the first busbar \textcircled{1} and the second busbar \textcircled{3}.

As shown in FIG. 9, at every position in the radial direction of the wafer, the growth speed of the thin film corresponding to the third busbar \textcircled{4} is lower than that corresponding to the first busbar \textcircled{1} and higher than that corresponding to the second busbar \textcircled{3}. As shown in FIG. 8, the average growth rate of the thin film on the surface of the wafer corresponding to the third busbar \textcircled{4} is 2.9127 μm/h, and the variation in film thickness uniformity is 3.67%.

Compared with the top liner 106 employing the plate, the top liner 206 generated by employing the third busbar \textcircled{4} has less influence on the uniformity of the thickness of the thin film on the surface of the wafer while increasing the source efficiency of the process gas and increasing the deposition rate of the thin film on the surface of the wafer, which may be neglected.

### Embodiment III

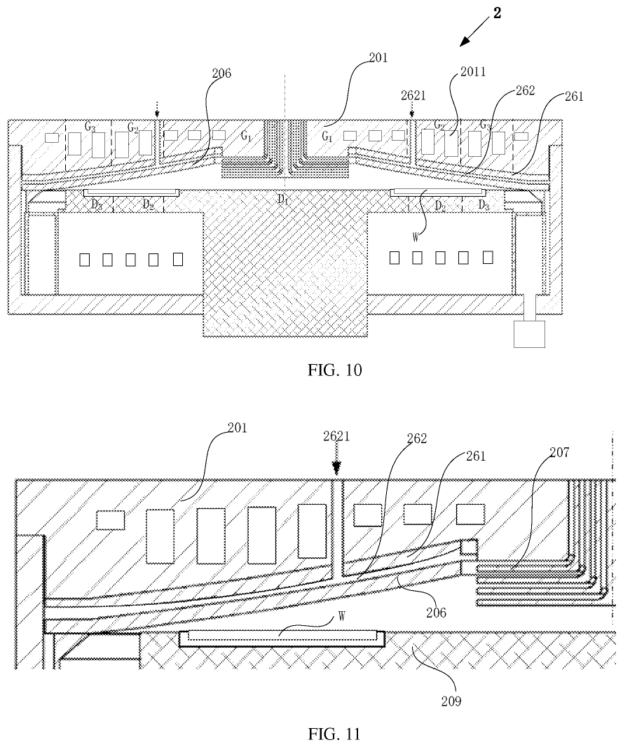

In this embodiment, as shown in FIG. 3 and FIG. 10, a coolant passage 2011 is disposed in the chamber lid 201. Owing to the excellent heat transfer between the chamber lid 201 and the top liner 206, the temperatures of the chamber lid 201 and the top liner 206 can be adjusted via the coolant passage 2011. Under ideal conditions, the temperature of the top liner 206 is desirably about 100 °C to 200 °C lower than the temperature of the susceptor. On the one hand, the deposition of the thin film on the surface of the top liner 206 may be reduced, such that particle contaminants in the reaction chamber 200 are effectively reduced, thereby increasing the yield of the wafer W and reducing the cleaning frequency of the reaction chamber 200. On the other hand, heat transfer still occurs between the top liner 206 and the process gas in the reaction chamber 200. Controlling the temperature of the top liner 206 can prevent the temperature of the process gas within the reaction chamber 200 from failing to meet process requirements due to an excessively low temperature of the top liner 206.

Due to the heat conduction caused by gas flow and the presence of cooling channels in the chamber, relatively large differences in thermal conductivity among various regions of the susceptor 209 are inevitably produced. In this embodiment, based on the temperature distribution of the susceptor 209 during the process, in the radial direction of the susceptor 209, the susceptor 209 is virtually divided into a plurality of concentric annular temperature zones, and the temperature difference between adjacent annular temperature zones exceeds a set temperature difference threshold. As shown in FIG. 10, in this embodiment, the susceptor is divided into three annular temperature zones D1, D2, and D3. The number of annular temperature zones is an example only and does not limit the present disclosure.

Along the radial direction of the chamber lid 201, the chamber lid 201 is virtually divided into a plurality of annular temperature regulation zones corresponding to the plurality of annular temperature zones. Each annular temperature zone radiates different amounts of heat to the corresponding annular region of the top liner. The distance between the coolant passage 2011 in the annular temperature regulation zone and the lower surface of the chamber lid 201 depends on the temperature of the corresponding annular temperature zone. As shown in FIG. 10, in this embodiment, the chamber lid 201 is divided into three annular temperature regulation zones G1, G2, and G3.

As shown in FIG. 10, the temperature of the annular temperature zone D2 is the highest, and correspondingly, the distance between the coolant passage 2011 in the annular temperature regulation zone G2 and the lower surface of the chamber lid 201 is the smallest. The temperature of the annular temperature zone D1 is the lowest, and correspondingly, the distance between the coolant passage 2011 in the annular temperature regulation zone G1 and the lower surface of the chamber lid 201 is the greatest. Thus, the temperature of the top liner 206 may be regulated according to regions, which is beneficial to reducing the temperature gradient of the top liner 206, thereby avoiding deformation of the top liner 206 due to thermal stress. By improving the uniformity of the temperature of the top liner 206, the uniformity of the temperature of the process gas in the reaction chamber 200 may also be improved, which is beneficial to growing a thin film with a uniform thickness on the surface of the wafer.

### Embodiment IV

In this embodiment, a temperature regulating mechanism is disposed between the chamber lid 201 and the top liner 206 to enhance the temperature regulating effect of the top liner 206. As shown in FIG. 3 and FIG. 11, the temperature regulating mechanism includes a thermal conductive plate 261 (made of aluminum or quartz), and an upper surface of the thermal conductive plate 261 is attached to a lower surface of the chamber lid 201.

As shown in FIG. 3 and FIG. 11, the temperature regulating mechanism further includes a gap 262 formed between the thermal conductive plate 261 and the top liner 206. The vapor deposition apparatus further includes a heat transfer gas input end 2621. As shown in FIG. 3 and FIG. 11, the heat transfer gas input end 2621 passes through the chamber lid 201 and the thermal conductive plate 261 for providing heat transfer gas to the gap 262.

It is easily understood that the thicker the thermal conductive plate 261, the greater the surface emissivity and the better the heat transfer effect of the thermal conductive plate 261. Based on the temperature distribution characteristics of the susceptor 209, in this embodiment, as shown in FIG. 11, along the direction away from the gas injection apparatus 207, the thickness of the thermal conductive plate 261 first increases and then decreases, and/or the surface emissivity of the thermal conductive plate 261 first increases and then decreases. Since the spacing between the chamber lid 201 and the top liner 206 is uniform everywhere, when the thermal conductive plate 261 becomes thicker, the gap 262 becomes smaller, and when the thermal conductive plate 261 becomes thinner, the gap 262 becomes larger. Therefore, along the direction away from the gas injection apparatus 207, the gap 262 becomes smaller first and then becomes larger.

In this embodiment, the thickness of the thermal conductive plate 261, the surface emissivity of the thermal conductive plate 261 and the size of the gap 262 change along with the temperature change of the susceptor 209, which is beneficial for regulating the temperature of the top liner 206 according to regions, improving the uniformity of the temperature of the top liner 206, and avoiding deformation and damage to the top liner 206 due to an excessively large temperature gradient.

In another embodiment, components of the heat transfer gas are adjustable. For example, the heat transfer gas may include nitrogen and argon, and these two types of gas have different thermal conductivities. By adjusting the flow ratio of nitrogen to argon, the thermal conductivity of the heat transfer gas can be regulated, thereby adjusting the temperature of the top liner 206 in real time. In deposition processes of different materials, the top liner 206 can be adjusted to different temperatures, thereby reducing deposits on the top liner 206. In an embodiment, the flow ratio range of nitrogen and argon is 2:1 to 3:1 (this is merely an example, and does not limit the present disclosure).

It should be understood that sequence numbers of the steps do not mean an execution sequence in the foregoing embodiments. The execution sequence of the processes should be determined based on functions and internal logic of the processes, and should not constitute any limitation on the implementation processes of embodiments of the present application.

The foregoing descriptions are merely specific embodiments of the present disclosure, and the scope of protection of the present disclosure is not limited thereto. Any person skilled in the art may readily conceive various equivalent modifications or substitutions within the technical scope disclosed by the present disclosure, and such modifications or substitutions shall fall within the scope of protection of the present disclosure. Therefore, the scope of protection of the present disclosure shall be subject to the scope of protection of the claims.

1. A vapor deposition apparatus, comprising a reaction chamber, a susceptor being disposed at a lower part inside the reaction chamber, and an upper surface of the susceptor being a wafer supporting surface, wherein the vapor deposition apparatus comprises:
a top liner, disposed in the reaction chamber and opposite to the wafer supporting surface, and a reaction area being formed between the top liner and the wafer supporting surface; and
a gas injection apparatus, the gas injection apparatus being configured to transversely inject a process gas into the reaction area, wherein
the top liner is formed by a second busbar rotating around a central shaft of the gas injection apparatus, the second busbar is formed by a first busbar rotating around a start point of the first busbar at a set angle in a vertical direction, and the first busbar has the start point close to the central shaft and an end point away from the central shaft; points x, y are any two points on the first busbar, vertical distances between the points x, y and the wafer supporting surface are denoted as h₁,h₂, respectively, horizontal distances between the points x, y and the central shaft are denoted as l₁,l₂, respectively, and the points x, y satisfy h₁×l₁=h₂×l₂; and
alternatively, the top liner is formed by a third busbar rotating around the central shaft of the gas injection apparatus, the third busbar is a straight line, and the third busbar and the first busbar share the start point and the end point.

2. The vapor deposition apparatus according to claim 1, wherein the angle is [−2°, 5°]; when the first busbar rotates around the start point in a direction close to the wafer supporting surface, the angle is defined as a negative value, and when the first busbar rotates around the start point in a direction away from the wafer supporting surface, the angle is defined as a positive value.

3. The vapor deposition apparatus according to claim 1, wherein the reaction chamber comprises a chamber lid, located above the top liner; and a coolant passage is disposed in the chamber lid.

4. The vapor deposition apparatus according to claim 3, wherein a heating apparatus is disposed below the susceptor; the susceptor is virtually divided into a plurality of annular temperature zones in a radial direction of the susceptor, and a temperature difference between adjacent annular temperature zones exceeds a set temperature difference threshold; the chamber lid is virtually divided into a plurality of annular temperature regulation zones corresponding to the plurality of annular temperature zones respectively in a radial direction of the chamber lid; and a distance between the coolant passage in the annular temperature regulation zone and a lower surface of the chamber lid depends on a temperature of the corresponding annular temperature zone.

5. The vapor deposition apparatus according to claim 3, wherein a temperature regulating mechanism is disposed between the chamber lid and the top liner.

6. The vapor deposition apparatus according to claim 5, wherein the temperature regulating mechanism comprises a thermal conductive plate, and an upper surface of the thermal conductive plate is attached to the lower surface of the chamber lid.

7. The vapor deposition apparatus according to claim 6, wherein the temperature regulating mechanism further comprises a gap formed between the thermal conductive plate and the top liner.

8. The vapor deposition apparatus according to claim 7, wherein the gap first decreases and then increases in a direction away from the gas injection apparatus.

9. The vapor deposition apparatus according to claim 8, wherein a thickness of the thermal conductive plate first increases and then decreases in the direction away from the gas injection apparatus.

10. The vapor deposition apparatus according to claim 7, wherein surface emissivity of the thermal conductive plate first increases and then decreases in the direction away from the gas injection apparatus.

11. The vapor deposition apparatus according to claim 7, wherein the vapor deposition apparatus further comprises a heat transfer gas input end and a heat transfer gas output end, configured to provide a flowing heat transfer gas to the gap.

12. The vapor deposition apparatus according to claim 11, wherein components of the heat transfer gas are adjustable.

13. The vapor deposition apparatus according to claim 1, wherein the vapor deposition apparatus further comprises a pumping ring, and the pumping ring is disposed around a lower lateral side of the susceptor.

14. The vapor deposition apparatus according to claim 13, wherein the pumping ring comprises an inner ring, an outer ring, and a ring top surface that connects the inner ring and the outer ring; and a plurality of pumping holes are formed in the ring top surface in a circumferential direction of the pumping ring.

15. The vapor deposition apparatus according to claim 13, wherein the vapor deposition apparatus further comprises a side liner, which is disposed around a periphery of the susceptor, and located between the top liner and the pumping ring.

16. The vapor deposition apparatus according to claim 15, wherein an upper end of the side liner is provided with a gas flow guide portion that extends in a direction toward the gas injection apparatus.

17. The vapor deposition apparatus according to claim 16, wherein the top liner further comprises a top liner supporting portion that extends from the end point in a direction away from the central shaft, and a bottom surface of the top liner supporting portion is attached to a top surface of the gas flow guide portion.

18. The vapor deposition apparatus according to claim 1, wherein the gas injection apparatus comprises gas outlet ends located at different heights, and the gas outlet end closest to the top liner is configured to supply an inert gas.

19. A top liner, used in a vapor deposition apparatus, wherein the vapor deposition apparatus comprises a reaction chamber, a susceptor being disposed at a lower part inside the reaction chamber, and an upper surface of the susceptor being a wafer supporting surface;
the top liner is disposed in the reaction chamber and opposite to the wafer supporting surface, and a reaction area is formed between the top liner and the wafer supporting surface; and
the vapor deposition apparatus further comprises a gas injection apparatus, the gas injection apparatus being configured to transversely inject a process gas into the reaction area;
the top liner is formed by a second busbar rotating around a central shaft of the gas injection apparatus, the second busbar is formed by a first busbar rotating around a start point of the first busbar at a set angle in a vertical direction, and the first busbar has the start point close to the central shaft and an end point away from the central shaft; points x, y are any two points on the first busbar, vertical distances between the points x, y and the wafer supporting surface are denoted as h₁, h₂, respectively, horizontal distances between the points x, y and the central shaft are denoted as l₁, l₂, respectively, and the points x, y satisfy h₁×l₁=h₂×l₂; and
alternatively, the top liner is formed by a third busbar rotating around the central shaft of the gas injection apparatus, the third busbar is a straight line, and the third busbar and the first busbar share the start point and the end point.

20. The top liner according to claim 19, wherein the angle is [−2°, 5°]; when the first busbar rotates around the start point in a direction close to the wafer supporting surface, the angle is defined as a negative value, and when the first busbar rotates around the start point in a direction away from the wafer supporting surface, the angle is defined as a positive value.
